(19) United States
(12) Patent Application Publication
(10) Pub. No.: US 2024/0032291 A1
(43) Pub. Date: Jan. 25, 2024

(54) NON-VOLATILE MEMORY, FABRICATION AND CONTROL METHODS THEREOF

(71) Applicant: HeFeChip Corporation Limited, Sai Ying Pun (HK)

(72) Inventor: Geeng-Chuan CHERN, Cupertino, CA (US)

(21) Appl. No.: 17/888,424

(22) Filed: Aug. 15, 2022

(30) Foreign Application Priority Data
Jul. 22, 2022 (CN) 202210874559.1

(51) Int. Cl. H01L 27/11524; H01L 27/11558; H01L 29/66

(52) U.S. Cl. CPC H01L 27/11524; H01L 27/11558; H01L 29/66825

(57) ABSTRACT

A non-volatile memory and fabrication method thereof are disclosed. The non-volatile memory includes at least one 2T memory cell. Each 2T memory cell includes a semiconductor substrate, a first stacked gate and a second stacked gate formed on the semiconductor substrate, and a drain region, a common source/drain region and a source region formed in the semiconductor substrate. The source region and the common source/drain region are both N-type doped, and the drain region includes an N-type doped region and a heavily P-type doped region formed in the N-type doped region. The 2T memory cell is capable of preventing erroneous data determination caused by over erase and has both a low programming current and a high reading current, which improves the performance of the non-volatile memory.

### CROSS-REFERENCE TO RELATED APPLICATION

This application claims the priority of Chinese patent application number 202210874559.1, filed on Jul. 22, 2022, the entire contents of which are incorporated herein by reference.

### TECHNICAL FIELD

The present invention relates to the field of semiconductor technology and, in particular, to a non-volatile memory and fabrication and control methods thereof.

### BACKGROUND

Non-volatile memory (NVM) has become one of the common memories used in computers, mobile phones, digital cameras and other electronic devices due to its capability of allowing repeated storage, readout and erasing of data and not losing the stored data upon system shutdown or loss of power.

A typical NVM memory cell includes a semiconductor substrate, a floating gate and a control gate. The control gate is disposed above the floating gate and separated from the floating gate by a dielectric layer. The floating gate is separated from the semiconductor substrate by a tunneling oxide layer. During an erase operation on such an NVM memory cell, it is difficult to control the number of electrons discharged from the floating gate. If too many electrons are removed, the floating gate may become positively charged. This phenomenon is called over erase, which may lead to early conduction of a channel under the floating gate before a voltage on the control gate reaches an operating voltage. The over erase issue results in an always “on” memory cell which cannot be switched between “on” and “off” states when the voltage on the control gate switches between the operating voltage and a non-operating voltage. This may cause erroneous data determination.

One method for overcoming the over erase issue involves the use of a program verify circuit designed to verify program operations on memory cells. However, such a program verify circuit is typically complicated. Another more commonly used method is to add a select transistor at a drain side of each memory cell and maintain a channel under the select transistor in an off state. In this way, even when the channel under the floating gate is switched on before the voltage on the control gate reaches the operating voltage due to over erase in the memory cell, the cell current path between the drain and source is cut off and there will be no cell current, thus preventing erroneous data determination.

With the shrinkage of NVM cell size, it is desirable to obtain NVMs with low programming current and high reading current while not suffering from erroneous data determination caused by over erase. However, existing NVMs cannot satisfy this requirement, and this is one of the current major challenges in the field of NVM.

### SUMMARY OF THE INVENTION

The present invention provides a non-volatile memory, which is capable of preventing erroneous data determination caused by over erase and has both a low programming current and a high reading current. The present invention also provides fabrication and control methods for such a non-volatile memory.

In one aspect, the present invention provides a non-volatile memory comprising at least one 2T memory cell. Each 2T memory cell comprises:
a semiconductor substrate;
a first stacked gate formed on the semiconductor substrate, wherein the first stacked gate comprises a tunneling dielectric layer, a floating gate, an inter-gate dielectric layer and a control gate;
a second stacked gate formed on the semiconductor substrate, wherein the second stacked gate comprises a select gate dielectric layer and a select gate;
a drain region formed in the semiconductor substrate and situated on a side of the first stacked gate away from the second stacked gate;
a common source/drain region formed in the semiconductor substrate and situated between the first stacked gate and the second stacked gate; and
a source region formed in the semiconductor substrate and situated on a side of the second stacked gate away from the first stacked gate.

Optionally, the source region and the common source/drain region are N-type doped regions, and the N-type doped region comprises a heavily N-type doped region and an N-type LDD region; and the drain region comprises an N-type doped region and a heavily P-type doped region formed in the N-type doped region, and the N-type doped region in the drain region extends laterally to a position below a portion of the first stacked gate.

Optionally, the non-volatile memory further comprises a mirrored 2T memory cell which shares the source region with the 2T memory cell, wherein a plurality of 2T memory cells and a plurality of mirrored 2T memory cells form a memory cell array.

Optionally, the control gates in the 2T memory cells and in the mirrored 2T memory cells are respectively connected to form control gate lines, wherein the select gates in the 2T memory cells and in the mirrored 2T memory cells are respectively connected to form word lines, and wherein the source regions are connected to form source lines.

Optionally, the control gate in each 2T memory cell is adjacent and parallel to the control gate in a corresponding mirrored 2T memory cell.

Optionally, the non-volatile memory further comprises:
an interlayer dielectric layer covering the 2T memory cells and the mirrored 2T memory cells;
a plurality of contact plugs extending through the interlayer dielectric layer, wherein each of the plurality of contact plugs is connected to a corresponding drain region; and
a plurality of bit lines, respectively connected to the drain regions in the 2T memory cells and in the mirrored 2T memory cells via the corresponding contact plugs.

Optionally, the semiconductor substrate is a P-type doped substrate, wherein the source region, the common source/drain region and the drain region in each 2T memory cell are formed in a top portion of the P-type doped substrate.

Alternatively, the semiconductor substrate may contain a triple-well structure comprising an N-type doped well in a P-type doped substrate and a P-type doped well in the N-type doped well, wherein the source region, the common source/drain region and the drain region in each 2T memory cell are formed in a top portion of the P-type doped well.

In another aspect, the present invention provides a method for fabricating a non-volatile memory, comprising the steps of:
providing a semiconductor substrate;
forming a plurality of isolation regions in the semiconductor substrate, adjacent isolation regions defining an active area therebetween;
forming a first stacked gate and a second stacked gate on the active area, wherein the first stacked gate comprises a tunneling dielectric layer, a floating gate, an inter-gate dielectric layer and a control gate; and the second stacked gate comprises a select gate dielectric layer and a select gate;
forming a drain region, wherein the drain region is situated on a side of the first stacked gate away from the second stacked gate, and wherein the drain region comprises an N-type doped region and a heavily P-type doped region formed in the N-type doped region; and
forming a source region and a common source/drain region, wherein the source region is situated on a side of the second stacked gate away from the first stacked gate, wherein the common source/drain region is situated between the first stacked gate and the second stacked gate, and wherein each of the source region and the common source/drain region is N-type doped.

Optionally, the formation of the drain region comprises:
successively implanting N-type ions and P-type ions into a portion of the active area on the side of the first stacked gate away from the second stacked gate to form the N-type doped region and the heavily P-type doped region.

Optionally, the N-type ions are implanted at an energy of from 80 KeV to 150 KeV and a dose of from 8E12 cm′ to 8E14 cm′.

Optionally, the P-type ions are implanted at an energy of from 5 KeV to 25 KeV and a dose of from 1E15 cm′ to 1E16 cm′.

Optionally, the formation of the source region and the common source/drain region comprises:
performing an LDD implantation process between the first stacked gate and the second stacked gate and on the side of the second stacked gate away from the first stacked gate;
forming spacers on sidewalls of the first stacked gate and the second stacked gate respectively; and
implanting N-type ions into the portion of the active area between the first stacked gate and the second stacked gate, and on the side of the second stacked gate away from the first stacked gate to form the common source/drain region and the source region.

Optionally, the formation of the first stacked gate and the second stacked gate comprises:
forming a tunneling dielectric layer and a select gate dielectric layer over the semiconductor substrate;
forming a first conductive material layer over the tunneling dielectric and the select gate dielectric layers and forming first openings in the first conductive material layer, wherein the first openings are located in positional correspondence with the isolation regions, and wherein the tunneling dielectric layer is exposed in the first openings;
forming an inter-gate dielectric layer on the first conductive material layer and forming second openings in the inter-gate dielectric layer, wherein the second openings are located on the select gate dielectric layer and in positional correspondence with the isolation regions, and wherein the first conductive material layer is exposed in the second openings; and
forming a second conductive material layer on the inter-gate dielectric layer and performing photolithography and etching processes on the second conductive material layer, the inter-gate dielectric layer and the first conductive material layer to form at least one gate, wherein the gate on the select gate dielectric layer is select gate.

Optionally, the first conductive material layer and the second conductive material layer are directly connected at locations corresponding to the isolation regions.

Optionally, subsequent to the formation of the source region, the drain region and the common source/drain region, the fabrication method further comprises:
forming a silicide layer on a top surface of each of the control gate, the select gate, the source region, the drain region and the common source/drain region;
depositing an interlayer dielectric layer and forming contact plugs extending through the interlayer dielectric layer and connecting to the respective drain regions; and
forming, on the interlayer dielectric layer, bit lines connected to the respective contact plugs.

Optionally, the N-type doped region in the drain region laterally extends to a position below a portion of the floating gate.

In one aspect, the present invention provides a method for controlling a non-volatile memory, comprising a program operation performed on a selected 2T memory cell in the non-volatile memory as defined above. The program operation comprises:
grounding the semiconductor substrate; grounding or floating either of the source region and the common source/drain region in the selected 2T memory cell; applying a preset negative bias voltage to the drain region in the selected 2T memory cell; and applying a preset positive bias voltage to the control gate in the selected 2T memory cell.

Optionally, the method further comprises an erase operation comprising:
grounding the semiconductor substrate; grounding or floating any one of the source region, the drain region and the common source/drain region in the selected 2T memory cell; and applying a preset negative bias voltage to the control gate in the selected 2T memory cell.

Optionally, the method further comprises a read operation comprising:
grounding the semiconductor substrate, the source region and the common source/drain region in the selected 2T memory cell; applying a preset read voltage to the control gate in the selected 2T memory cell; applying a preset positive bias voltage to the drain region in the selected 2T memory cell; and applying a power supply voltage to the select gate in the selected 2T memory cell.

In the non-volatile memory provided in the present invention, each 2T memory cell includes a semiconductor substrate, a first stacked gate and a second stacked gate formed on the semiconductor substrate, and a source region, a common source/drain region and a drain region all formed in the semiconductor substrate. The first stacked gate and the drain region and common source/drain region located on opposite sides thereof form an N-channel memory transistor. The second stacked gate and the common source/drain region and source region located on opposite sides thereof form an N-channel select transistor. The N-channel select transistor is located on a side of the N-channel memory transistor proximal to the source region. Such a non-volatile memory may bring about the following advantages.

Firstly, even when the channel under the floating gate tends to be turned on before the control gate voltage reaches the operating voltage due to over erase, the N-channel select transistor can cut off the channel between the common source/drain region and the source region to prevent the channel of the 2T memory cell from being turned on. This can avoid erroneous data determination caused by over erase.

Secondly, in the 2T memory cell which is a two-transistor (2T) structure consisting of the N-channel memory transistor and the N-channel select transistor, since the mobility of electrons is higher than that of holes, the use of a relatively high reading current is allowed.

Thirdly, the drain region in the 2T memory cell includes an N-type doped region and a heavily P-type doped region in the N-type doped region. During a program operation, electrons are concentrated in the N-type doped region, resulting in a lower band-to-band tunneling voltage of a P+/N junction formed by the heavily P-type doped region and the N-type doped region, and hence a high probability of tunneling. Under the action of an appropriate control gate voltage and drain voltage, electrons that have tunneled can be injected into the floating gate, requiring less electrons from the channel and allowing the use of a lower programming current.

Therefore, the 2T memory cell is capable of preventing erroneous data determination caused by over erase and has both a low programming current and a high reading current, which provides the non-volatile memory with an improved performance.

The fabrication and control methods provided in the present invention have the same or similar advantages as above.

### BRIEF DESCRIPTION OF THE DRAWINGS

FIG. 1 is a schematic cutaway view of 2T memory cells in a non-volatile memory according to an embodiment of the present invention.

FIG. 2 is a schematic circuit diagram of a memory cell array in a non-volatile memory according to an embodiment of the present invention.

FIG. 3 is a schematic plan view of the memory cell array of FIG. 2.

FIGS. 4a to 11c are schematic cutaway views of structures formed during the fabrication of a non-volatile memory according to an embodiment of the present invention.

Description of Reference Numerals in Drawings:
100 - Semiconductor Substrate; 110 - First stacked gate; 111 - Tunneling Dielectric Layer; 113 - Inter-gate Dielectric Layer; 120 - Second stacked gate; 121 -Select Gate Dielectric Layer; 122 - Select Gate; 115, 123 - Spacer; 130 - Drain Region; 131 - N-type Doped Region; 132 - Heavily P-type Doped Region; 140 -Common Source/Drain Region; 150 - Source Region; 101 - Silicide Layer; 160 -Interlayer Dielectric Layer; 161 - Contact Plug; 112 - First Conductive Material Layer; 112a-First Opening; 114 - Second Conductive Material Layer; 113a-Second Opening; 10, 20 - Anisotropic Dry Etching Process.

### DETAILED DESCRIPTION

The non-volatile memory and fabrication and control methods thereof will be described in greater detail below with reference to the accompanying drawings and particular embodiments. From the following description, advantages and features of the present invention will become more apparent. It is to be noted that, as used herein, the terms “first”, “second” and the like may be used to distinguish between similar elements without necessarily implying any particular ordinal or chronological sequence. It is to be understood that the terms so used are interchangeable. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

It is to be understood that the drawings are all provided in a very simplified form not necessarily drawn to exact scale for the only purpose of helping to explain the disclosed embodiments in a more convenient and clearer way. Additionally, the spatially relative terms are intended to encompass different orientations of the device in use or operation in addition to the orientation depicted in the figures. For example, if the device in the figures is inverted or otherwise oriented (e.g., rotated), the exemplary term “over” can encompass an orientation of “under” and other orientations. Throughout the drawings, if any component is identical to a labeled one, although such components may be easily identifiable in all the figures, in order for a more clear description of labels to be obtained, not all identical components are labeled and described in the following description and accompanying drawings.

Embodiments of the present invention relate to a non-volatile memory including at least one two-transistor (2T) memory cell as described in the following embodiments. The 2T memory cell is so structured that, in the course of the non-volatile memory being controlled to perform program, erase and read operations on the 2T memory cell, erroneous data determination caused by over erase is prevented and the use of a low programming current and a high reading current is allowed. As a result, the performance of the non-volatile memory according to embodiments of the present invention is improved over conventional ones. According to embodiments of the present invention, the non-volatile memory may include at least one 2T memory cell, and a multitude of such 2T memory cells may form a memory cell array. According to embodiments of the present invention, the non-volatile memory may be any device or apparatus including the 2T memory cells.

FIG. 1 is a cutaway view showing the structure of a 2T memory cell and a mirrored 2T memory cell, which are arranged adjacent to each other, in a non-volatile memory according to an embodiment of the present invention. The mirrored 2T memory cell and the 2T memory cell share a common source region 150. A plurality of the 2T memory cells and mirrored 2T memory cells form a memory cell array. Referring to FIG. 1, each 2T memory cell in the non-volatile memory includes a semiconductor substrate 100, a first stacked gate 110 and a second stacked gate 120 formed on the semiconductor substrate 100, a drain region 130, a common source/drain region 140 and a source region 150 which are formed in the semiconductor substrate 100. Specifically, the first stacked gate 110 includes, stacked sequentially from the bottom upward, a tunneling dielectric layer 111, a floating gate (FG), an inter-gate dielectric layer 113 and a control gate (CG), and the second stacked gate 120 includes, stacked sequentially from the bottom upward, a select gate dielectric layer 121 and a select gate 122 (in this embodiment, the select gate 122 is connected to a word line (WL)). In addition, the 2T memory cell also includes a spacer 115 on a sidewall of the first stacked gate 110 and a spacer 123 on a sidewall of the second stacked gate 120.

In the 2T memory cell, both the source region 150 and the common source/drain region 140 are heavily N-type doped (N+) regions. The N-type dopant ions are, for example, of phosphorus (P) or arsenic (As). The drain region 130 includes an N-type doped (N) region 131 and a heavily P-type doped (P+) region 132 formed in the N-type doped region 131. The drain region 130 and the common source/drain region 140 are respectively located on opposite sides of the first stacked gate 110, thus making up an N-channel memory transistor. The common source/drain region 140 and the source region 150 are respectively located on opposite sides of the second stacked gate 120, thus making up an N-channel select transistor.

The semiconductor substrate 100 may be, among others, a silicon substrate, a germanium (Ge) substrate, a silicon-germanium substrate, a silicon-on-insulator (SOI) substrate or a germanium-on-insulator (SOI) substrate. The semiconductor substrate 100 may include a doped epitaxial layer, a graded semiconductor layer and a semiconductor layer located on top of a semiconductor layer of another type (e.g., a silicon layer on a silicon-germanium layer). Depending on the design requirements, certain dopant ions may be implanted into the semiconductor substrate 100 to modify its electrical parameters. In the semiconductor substrate 100, an active area and an isolation region (not shown in FIG. 1) that isolates the active area may be formed. The aforementioned drain region 130, common source/drain region 140 and source region 150 may be formed in the active area.

In this embodiment, the semiconductor substrate 100 is a P-type doped substrate (i.e., it is overall P-type doped). Additionally, it is, for example, a P-type doped silicon (P—Si) substrate. The drain region 130, common source/drain region 140 and source region 150 are directly formed in an upper portion of the P-type doped substrate. In some other embodiments, the semiconductor substrate 100 may be implemented as a triple-well structure. Specifically, it is a triple-well structure with an N-type doped well in the P-type doped substrate and a P-type doped well in the N-type doped well. The P-type doped well is isolated from the P-type doped substrate by the N-type doped well. The 2T memory cell is disposed on the triple-well structure, with the drain region 130, common source/drain region 140 and source region 150 being formed in a top portion of the P-type doped well. The N- and P-type doped wells in this triple-well structure may be respectively electrically connected to the outside via associated pick-up regions both extending to the top surface of the semiconductor substrate 100 and differing from the drain region 130, common source/drain region 140 and source region 150.

The 2T memory cell may further include N-type lightly doped drain (LDD) regions in the semiconductor substrate 100 respectively around the common source/drain region 140 and the source region 150. The LDD regions may be formed in a known manner so as to have a concentration of N-type dopant ions lower than concentrations of N-type dopant ions in the common source/drain region 140 and in the source region 150. In this embodiment, the LDD region around the source region 150 extends from a sidewall of the LDD region to a position below the select gate dielectric layer 121. The LDD region around the common source/drain region 140 extends from the common source/drain region 140 to a position below the tunneling dielectric layer 111 and to a position below the select gate dielectric layer 121.

Additionally, the drain region 130 is doped differently from the common source/drain region 140 and the source region 150. The drain region 130 includes the N-type doped region 131 and the heavily P-type doped region 132 formed in the N-type doped region 131. During operation of the 2T memory cell, the heavily P-type doped region 132 is applied with a drain voltage. The N-type doped region 131 surrounds the heavily P-type doped region 132 at both one side and the bottom thereof. A concentration of N-type dopant ions in the N-type doped region 131 is, for example, lower than or equal to the concentrations of N-type dopant ions in the common source/drain region 140 and in the source region 150. A depth of the N-type doped region 131 in the semiconductor substrate 100 is, for example, greater than a depth of either of the common source/drain region 140 and the source region 150. The N-type doped region 131 extend vertically to the top surface of the semiconductor substrate 100 and laterally to a position below a portion of the first stacked gate. This facilitates injection of electrons from the drain region 130 through the tunneling dielectric layer 111 into the floating gate (FG) during a program operation.

Referring to FIG. 1, the 2T memory cell includes an N-channel memory transistor and an N-channel select transistor. The N-channel memory transistor includes the first stacked gate 110, as well as the drain region 130 and the common source/drain region 140, which are situated on opposite sides of the first stacked gate 110 and serve as a drain region and a source region of the N-channel memory transistor, respectively. The N-channel select transistor includes the second stacked gate 120, as well as the common source/drain region 140 and the source region 150, which are situated on opposite sides of the second stacked gate 120 and serve as a drain region and a source region of the N-channel select transistor, respectively. Through the common source/drain region 140, the source region of the N-channel memory transistor and the drain region of the N-channel select transistor serve as a common junction.

The first stacked gate 110 includes the tunneling dielectric layer 111, the floating gate (FG), the inter-gate dielectric layer 113 and the control gate (CG), which are stacked sequentially from the bottom upward over the semiconductor substrate 100. The second stacked gate 120 includes the select gate dielectric layer 121 and the select gate 122, which are stacked sequentially from the bottom upward over the semiconductor substrate 100. The tunneling dielectric layer 111 and the select gate dielectric layer 121 that serve as tunneling dielectrics in the N-channel memory transistor and the gate dielectric in the N-channel select transistor, respectively, may include silica (SiO₂), silicon oxynitride (SiON), hafnium oxide (HfO) or another suitable material and have a thickness in the range of, for example, from 6 nm to 12 nm and from 2 nm to 10 nm, respectively. Here, the thickness of the tunneling dielectric layer 111 is, for example, difference or equal to the thickness of the select gate dielectric layer 121. The floating gate (FG), the control gate (CG) and the select gate 122 may be formed of doped polycrystalline silicon. It is to be noted that the select gate 122 shown in FIG. 1 includes upper and lower layers separated by the inter-gate dielectric layer 113, which are referred to as upper and lower select gate layers, respectively. However, the upper and lower layers may be electrically connected to each other elsewhere in the 2T memory cell. For example, the upper and lower select gate layers may be directly joined together at a location corresponding to an isolation region. In this embodiment, the inter-gate dielectric layer includes an ONO (SiO₂/SiN/SiO₂) stack, SiO₂ or silicon nitride (SiN). However, the present embodiment is not so limited. The sidewalls of the first stacked gate 110 and the second stacked gate 120 may be covered with the spacers. The 2T memory cell may further include a self-aligned silicide layer 101 formed over top surfaces of the aforementioned control gate (CG) and select gate 122 (upper select gate layer), as well as over top surfaces of the source region 150, drain region 130 and common source/drain region 140.

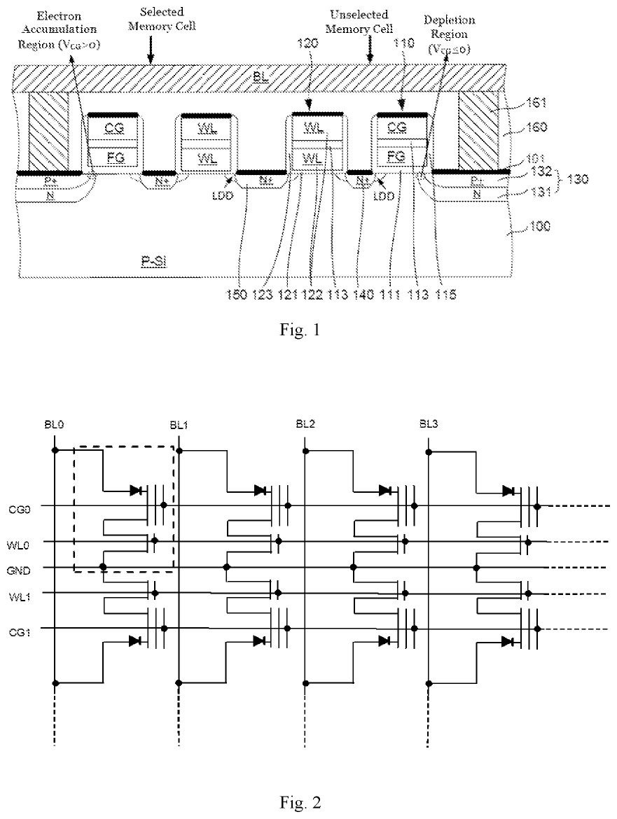

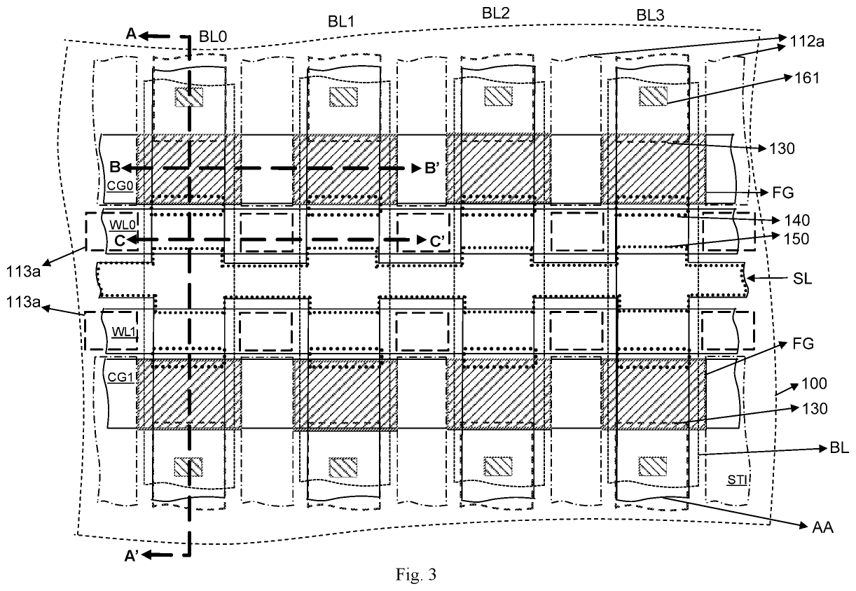

A non-volatile memory according to embodiments of the present invention includes a memory cell array, for example. The memory cell array may include a plurality of the above-described 2T memory cells and mirrored 2T memory cells. FIG. 2 is a schematic circuit diagram of a memory cell array in a non-volatile memory according to an embodiment of the present invention. The dashed-line box in FIG. 2 indicates one 2T memory cell. FIG. 3 is a schematic plan view of the memory cell array shown in FIG. 2. FIG. 3 depicts the locations and ranges of multiple constituent elements in FIG. 2 on the surface of the semiconductor substrate 100. Referring to FIGS. 2 and 3, the control gates in the individual 2T memory cells and mirrored 2T memory cells are connected one by one to form control gate lines (CG0, CG1, . . . . in FIGS. 2 and 3). The select gates in the individual 2T memory cells and mirrored 2T memory cells are connected one by one to form word lines (WL0, WL1, . . . . in FIGS. 2 and 3). The source regions 150 in the individual 2T memory cells and mirrored 2T memory cells are connected one by one to form source lines (SL) (which are grounded (“GND” in FIG. 2) in this embodiment). The drain regions 130 in the 2T memory cells and mirrored 2T memory cells are individually connected to bit lines (BL) (BL0, BL1, BL2, BL3, . . . in FIGS. 2 and 3). The memory cell array may include at least one control gate line, at least one word line and at least one bit line. With reference to FIG. 1, the non-volatile memory may further include an interlayer dielectric layer 160 on top of the semiconductor substrate 100 and a plurality of contact plugs 161 each extending through the interlayer dielectric layer 160. The interlayer dielectric layer 160 covers the individual 2T memory cells and mirrored 2T memory cells, and the aforementioned bit lines (BL) in the memory cell array are connected to the drain regions 130 in the individual 2T memory cells and mirrored 2T memory cells via the respective contact plugs 161. For example, the control gates of the 2T memory cells are adjacent and parallel to the control gates of the mirrored 2T memory cells.

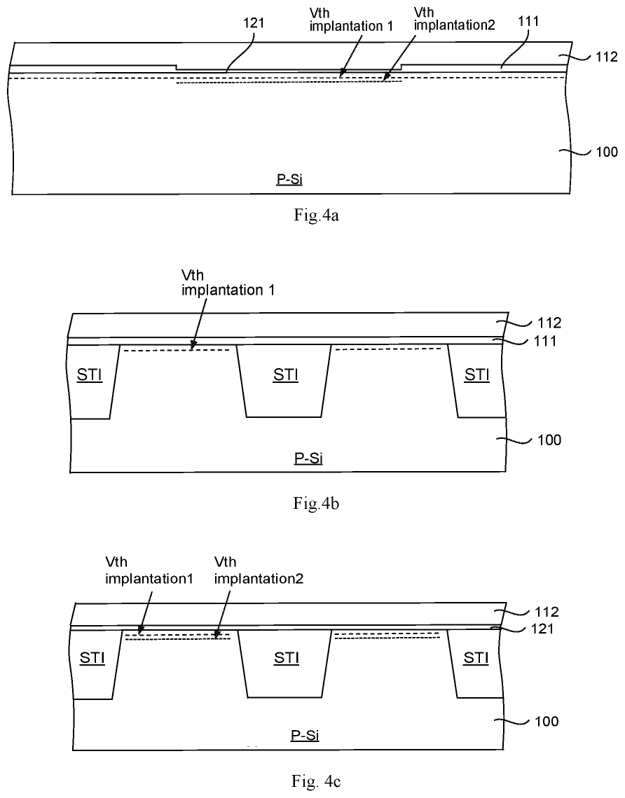

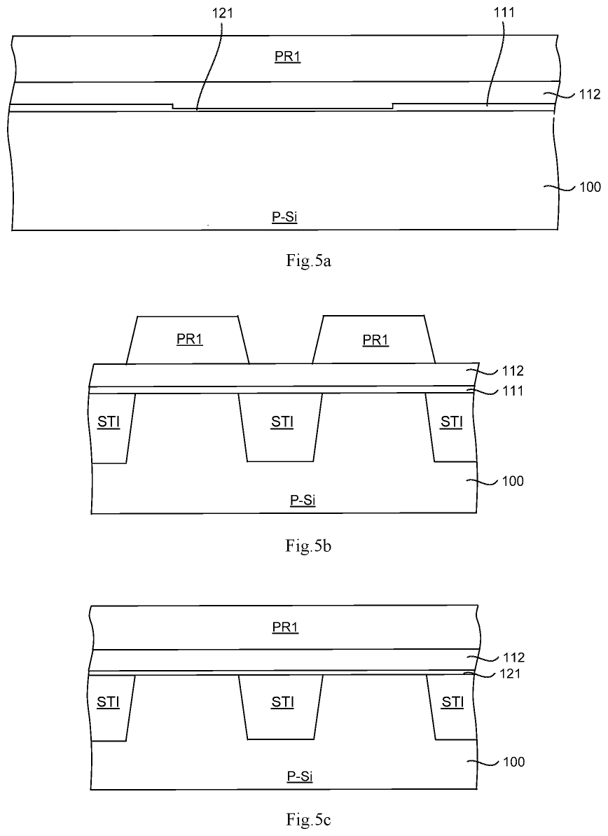

Embodiments of the present invention also relate to a fabrication method for a non-volatile memory. The method can be used to fabricate the non-volatile memories according to the foregoing embodiments. FIGS. 4a to 11c are schematic cutaway views of structures formed in the fabrication method according to an embodiment of the present invention. FIGS. 4a, 4b and 4c are schematic cutaway views of a structure at a single process node along dashed lines A-A′, B-B′ and C-C′ in FIG. 3, respectively. FIGS. 5a, 5b and 5c are schematic cutaway views of a structure at a single process node along dashed lines A-A′, B-B′ and C-C′ in FIG. 3, respectively. This applied to the other figures. The fabrication method is explained below with reference to FIGS. 3 to 11c.

Referring to FIGS. 4a to 4c, in a first step, a semiconductor substrate 100 is provided, and a plurality of isolation regions are formed in the semiconductor substrate 100. An active area (AA) is defined between every adjacent isolation regions. The isolation regions are, for example, shallow trench isolations (STI).

Specifically, according to this embodiment, the fabrication method can be used to fabricate a memory cell array as shown in FIGS. 2 and 3, which includes a plurality of 2T memory cells and mirrored 2T memory cells, which share common source regions. Subsequent to the formation of the isolation regions and the active areas (AA), the semiconductor substrate 100 has the plurality of isolation regions and a plurality of the active areas defined by the isolation regions. The isolation regions and the active areas are alternately arranged.

In a second step, first stacked gates 110 and second stacked structures 120 are formed on the semiconductor substrate 100, as described in detail below.

Referring to FIGS. 4a to 4c, at first, a tunneling dielectric layer 111 and a select gate dielectric layer 121 are formed over a surface of the semiconductor substrate 100. The formation may be accomplished by a thermal oxidation process. The tunneling dielectric layer 111 and the select gate dielectric layer 121 may both include silica (SiO₂), silicon oxynitride (SiON), hafnium oxide (HfO) or another suitable material. A thickness of the tunneling dielectric layer 111 is approximately between 6 nm and 12 nm. A thickness of the select gate dielectric layer 121 is approximately between 2 nm and 10 nm. In this embodiment, the tunneling dielectric layer 111 and the select gate dielectric layer 121 are not formed simultaneously, and the thickness of the select gate dielectric layer 121 is difference or equal to the thickness of the tunneling dielectric layer 111. Both the tunneling dielectric layer 111 and the select gate dielectric layer 121 cover the active areas and optionally the isolation regions. The tunneling dielectric layer 111 and the select gate dielectric layer 121 both span over each active area to allow gates of two transistors (one N-channel memory transistor and one N-channel select transistor) of one 2T memory cell to be formed respectively on the tunneling dielectric layer 111 and the select gate dielectric layer 121 in the specific active area.

In an optional embodiment, after the tunneling dielectric layer 111 and the select gate dielectric layer 121 are formed, at least one ion implantation process may be performed on the active areas in the semiconductor substrate 100 to adjust a threshold voltage (Vth) of the gates of the 2T memory cells to be formed. For example, a P-type dopant (e.g., boron (B) or boron difluoride (BF2)) may be implanted before or after the formation of the tunneling dielectric layer 111 and the select gate dielectric layer 121 into the semiconductor substrate 100 at energy of from 10 KeV to 20 KeV and a dose of from 1E12 cm⁻² to 1E13 cm⁻². Ion implantation may be performed separately in regions of the tunneling dielectric layer 111 and the select gate dielectric layer 121. The dashed lines in FIGS. 4a to 4c indicate locations where ion implantation is performed for threshold voltage adjustment. In addition to the ion implantation process performed through the tunneling dielectric layer 111 and the select gate dielectric layer 121 (indicated by “Vth Implantation 1”), another ion implantation process may be performed through the second select gate dielectric layer 121 (“Vth Implantation 2”). After the completion of the ion implantation process for threshold voltage adjustment, a rapid thermal annealing (RTA) or furnace annealing process may be performed to activate the implanted dopant ions in the semiconductor substrate 100.

Subsequently, referring to FIGS. 4a to 4c, a first conductive material layer 112 is sequentially formed, for example, by a chemical vapor deposition (CVD) process. The first conductive material layer 112 may include heavily N-type doped (N+) polycrystalline silicon, silicon-rich silicon oxynitride (silicon-rich SiON) or another suitable material. A thickness of the first conductive material layer 112 is approximately between 50 nm and 150 nm. In this embodiment, the first conductive material layer 112 is to be processed to form floating gates (FG) in first stacked gates 110 and lower select gate layers in second stacked gates 120 as defined above.

After that, referring to FIGS. 5a to 5c, a patterned photoresist (PR) layer, referred to hereinafter as the photoresist layer PR1, is formed on the first conductive material layer 112 using exposure and development processes. The openings in the photoresist layer PR1 correspond to the respective isolation regions covered by the tunneling dielectric layer 111, and in which the first conductive material layer 112 is exposed.

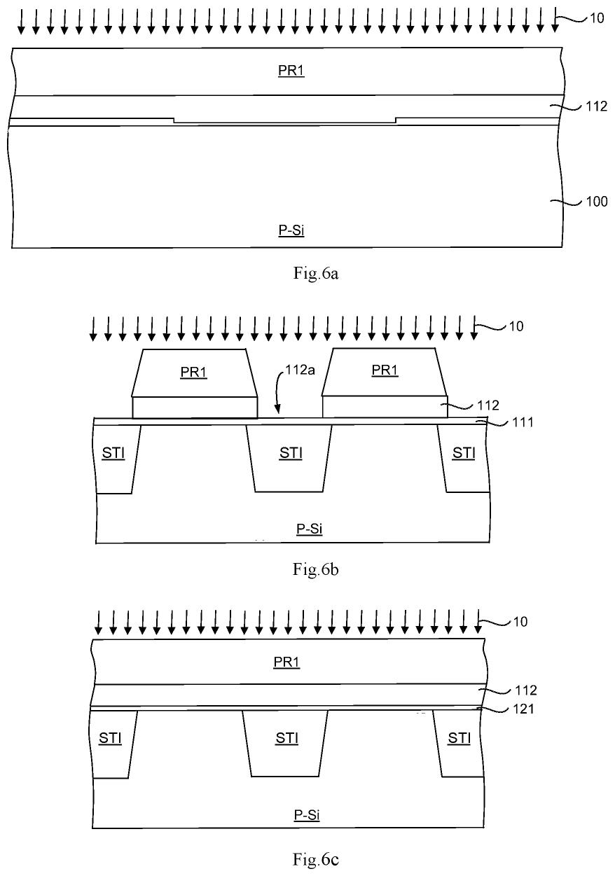

Next, referring to FIGS. 6a to 6c, with the photoresist layer PR1 serving as a mask, the first conductive material layer 112 is etched so that first openings 112a are formed in the first conductive material layer 112. With reference to FIG. 3, the first openings 112a are located on the tunneling dielectric layer 111 and are in positional correspondence with the respective isolation regions. This can be accomplished by an anisotropic dry etching process 10. In this embodiment, the first openings 112a delimit the floating gates (FG) in the first stacked gates 110 in vertical (or y-direction) direction.

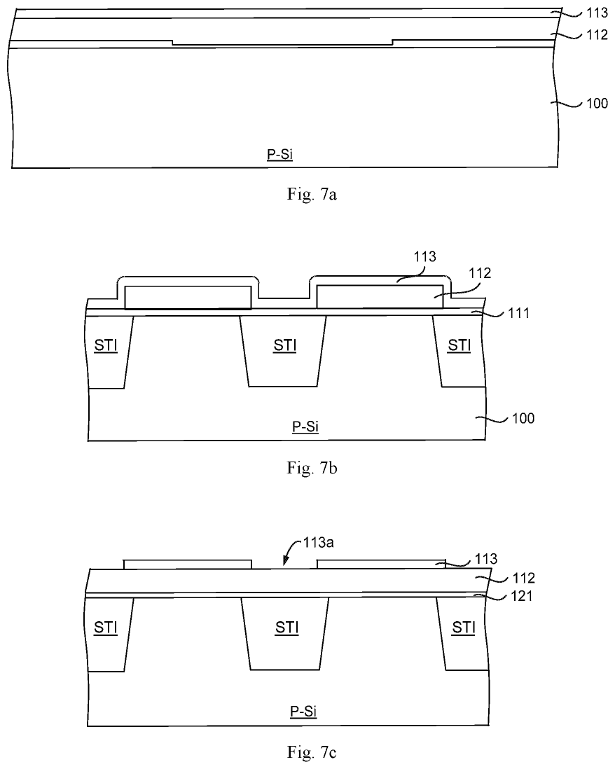

Referring to FIGS. 7a to 7c, subsequent to the formation of the first openings 112a, the photoresist layer PR1 is removed, and an inter-gate dielectric layer 113 is formed. The inter-gate dielectric layer 113 may include at least one of an oxide, a nitride and an oxynitride. For example, the inter-gate dielectric layer 113 may be an ONO stack including, stacked sequentially from the bottom upward, a lower oxide layer with a thickness of approximately from 3 nm to 8 nm, a nitride layer with a thickness of approximately from 4 nm to 10 nm and an upper oxide layer with a thickness of approximately from 3 nm to 8 nm. Next, with reference to FIG. 3, second openings 113a may be formed in the inter-gate dielectric layer 113 by performing photolithography and etching processes on the inter-gate dielectric layer 113. The second openings 113a expose the first conductive material layer 112, corresponding to the position of the respective isolation regions. In the second openings 113a, portions of the first conductive material layer 112 that overlies select gate dielectric layer 121 in the respective isolation regions are exposed, enabling the first conductive material layer 112 to be brought into electrical contact with the upper select gate layers in the second stacked gates 120 to be formed subsequently through the second openings 113a. In this way, the portions of the first conductive material layer 112 exposed in the second openings 113a form a part of the select gates.

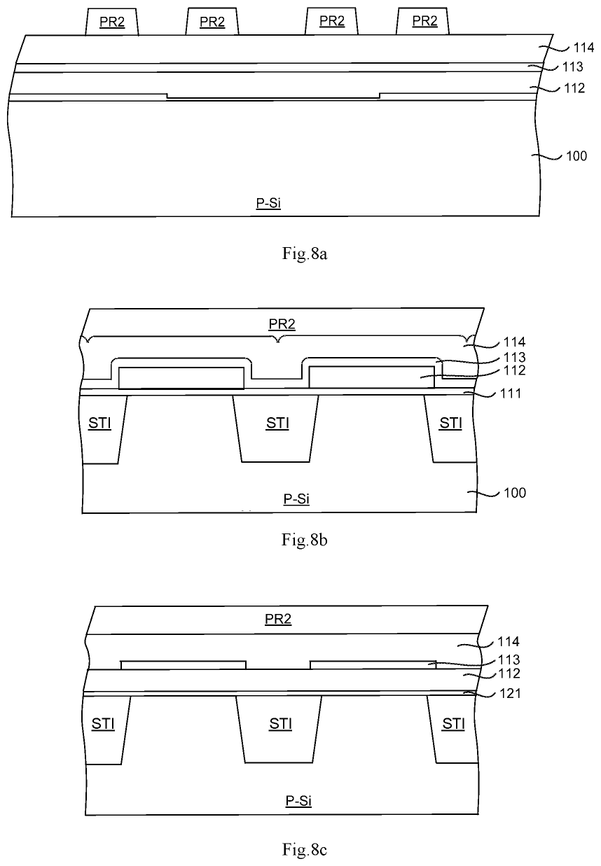

Afterward, referring to FIGS. 8a to 8c, a second conductive material layer 114 is formed over the semiconductor substrate 100, for example, by a chemical vapor deposition (CVD) process. The second conductive material layer 114 may include heavily N-type doped (N+) polycrystalline silicon, silicon-rich silicon oxynitride (silicon-rich SiON) or another suitable material. A thickness of the second conductive material layer 114 is approximately between 80 nm and 250 nm. Next, a patterned photoresist layer, referred to hereinafter as the photoresist layer PR2, is formed on the second conductive material layer 114. Openings in the photoresist layer PR2 exposes portions of the second conductive material layer 114 and define locations where control gates (CG) in the first stacked gates 110 and upper select gate layers in the second stacked gates 120 are to be formed.

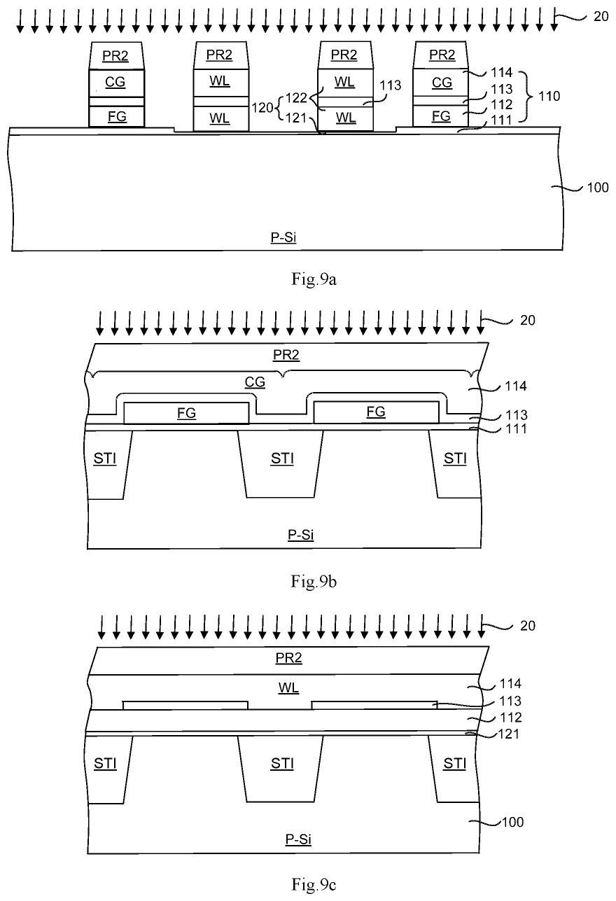

Subsequently, referring to FIGS. 9a to 9c, with the photoresist layer PR2 serving as a mask, the second conductive material layer 114, the inter-gate dielectric layer 113 and the first conductive material layer 112 are etched, resulting in the formation a plurality of gates of transistors. The at least one gate of the transistors on the select gate dielectric layer 121 are select gates 122. In this embodiment, the plurality of transistors correspond to 2T memory cells and mirrored 2T memory cells, which share common source regions.

In this embodiment, after the second conductive material layer 114, the inter-gate dielectric layer 113 and the first conductive material layer 112 are etched, the first conductive material layer 112, the inter-gate dielectric layer 113 and the second conductive material layer 114 over the tunneling dielectric layer 111 and the select gate dielectric layer 121 are partitioned into separate individual portions, resulting in the formation of the first stacked gates 110 and the second stacked gates 120. This can be accomplished using an anisotropic dry etching process 20. Each of the stacked gates 110 includes, stacked sequentially from the bottom upward over the semiconductor substrate 100, the tunneling dielectric layer 111, the floating gate (FG), the inter-gate dielectric layer 113 and the control gate (CG), and each of the second stacked gates 120 includes, stacked sequentially from the bottom upward over the semiconductor substrate 100, the select gate dielectric layer 121 and the select gate 122. In each select gate 122, the first conductive material layer 112 (lower select gate layer) and the second conductive material layer 114 (upper select gate layer) are electrically connected to each other.

In this embodiment, the first conductive material layer 112 is directly connected to the second conductive material layer 114 at locations corresponding to the isolation regions. Specifically, the first conductive material layer 112 located on the select gate dielectric layer 121 is brought into electrical contact with the second conductive material layer 114 by the second openings 113a formed in the inter-gate dielectric layer 113. Compared with the use of a single conductive material layer, the select gates 122 resulting from processing the first conductive material layer 112 and the second conductive material layer 114 according to this embodiment and the associated word lines exhibit lower resistance which contributes to a lower word line delay and a high reading speed. Preferably, widths of the select gates 122 (or the word lines (WL)) are greater than widths of the second openings 113a. As such, during the anisotropic dry etching process 20 for forming the first stacked gates 110 and the second stacked gates 120, the amount of material to be etched away from the tunneling dielectric layer 111 and the select gate dielectric layer 121 and the etching speed thereof are substantially the same. Compared with the widths of the second openings 113a which are so large that the select gates 122 are encompassed by the second openings 113a, this can avoid the select gate dielectric layer 121 from being over-etched and damaged.

After the completion of the above step, the photoresist layer PR2 is removed. Referring to FIGS. 2 and 3, in this embodiment, subsequent to the formation of the first stacked gates 110 and the second stacked gates 120, the remainder of the second conductive material layer 114 forms control gate lines (CG0, CG1, . . . . in FIGS. 2 and 3) and the word lines (WL) (WL0, WL1, . . . in FIGS. 2 and 3). The control gate lines are formed by the control gates (CG), and the word lines (WL) by the select gates 122, in the plurality of 2T memory cells.

In a third step, the source region 150, drain regions 130 and common source/drain regions 140 are formed in the active areas in the semiconductor substrate 100. The source regions 150 and the common source/drain regions 140 may be formed in a single ion implantation process, while the drain regions 130 are formed in a separate ion implantation process. In this embodiment, the ion implantation process for forming the drain regions 130 precedes the ion implantation process for simultaneously forming the source region 150 and the common source/drain region 140. In some other embodiments, the ion implantation process for simultaneously forming the source region 150 and the common source/drain region 140 may precede the ion implantation process for forming the drain regions 130.

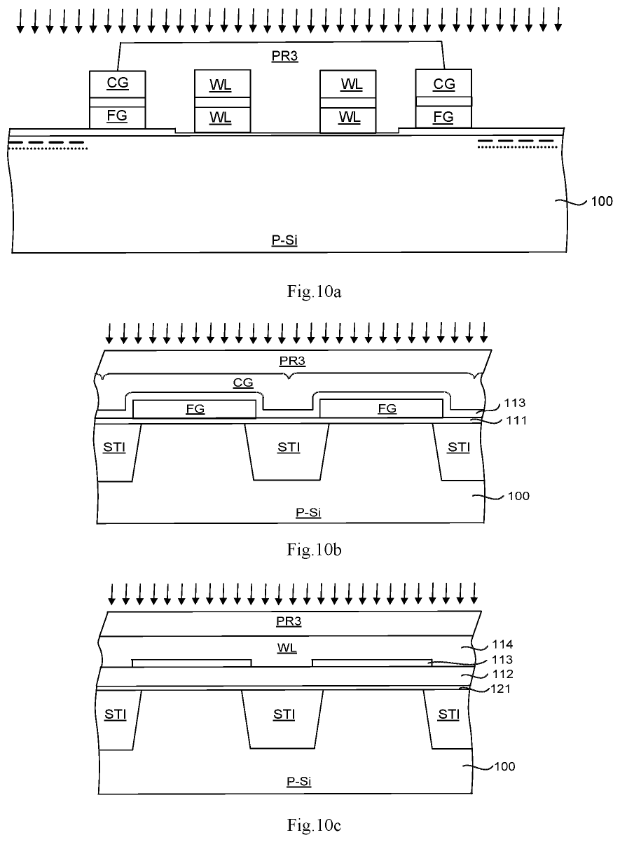

Referring to FIGS. 10a to 10c, the formation of the drain regions 130 in the semiconductor substrate 100 may include, at first, forming a patterned photoresist layer, referred to hereinafter as the photoresist layer PR3, over the semiconductor substrate 100. Openings in the photoresist layer PR3 expose the active areas where the drain regions are to be formed. In this embodiment, the openings in the photoresist layer PR3 are located on the side of the first stacked gates 110 away from the second stacked gates 120, and sidewalls of the first stacked gates 110 and a surface of the tunneling dielectric layer 111 on the same side are exposed in the openings. Subsequently, with the photoresist layer PR3 serving as a mask, N-type ions and P-type ions are successively implanted into the active areas. The P-type ions are implanted to a depth (as indicated by the dashed lines in FIG. 10a) that is, for example, shallower than a depth where the N-type ions are implanted (as indicated by the dotted lines in FIG. 10a). For example, ions of an N-type dopant (e.g., phosphorus (P) or arsenic (As)) are implanted as said N-type ions through the tunneling dielectric layer 111 into the semiconductor substrate 100 at energy of from 80 KeV to 150 KeV and a dose of from 8E12 cm′ to 8E14 cm′, and ions of a P-type dopant (e.g., boron (B) or boron difluoride (BF²)) are implanted as said P-type ions through the tunneling dielectric layer 111 into the semiconductor substrate 100 at energy of from 5 KeV to 25 KeV and a dose of from 1E15 cm′ to 1E16 cm′. The arrows in FIGS. 10a to 10c indicate the direction in which the N- and P-type ions are implanted. In this embodiment, the direction in which the N- and P-type ions are implanted is the direction of a normal of the surface of the semiconductor substrate 100. In some other embodiments, the direction in which the N- and P-type ions are implanted may be inclined at a predetermined angle from the direction of the normal of the surface of the semiconductor substrate 100. After the implantation of the N- and P-type ions for forming the drain region 130 is completed, the photoresist layer PR3 is removed, and the implanted ions are annealed, resulting in the formation of the drain regions 130 in the semiconductor substrate 100. Each of the drain regions 130 includes an N-type doped region 131 and a heavily P-type doped region 132 formed in the N-type doped region 131. The N-type doped region 131 and the heavily P-type doped region 132 make up a P+/N junction. In this embodiment, the drain regions 130 are situated on the side of the first stacked gates 110 away from the second stacked gates 120, and the N-type doped regions 131 extend vertically to the top surface of the semiconductor substrate 100 and laterally to a position below a portion of the first stacked gate 110. In some other embodiments, an annealing process may be performed after the drain regions 130, the source regions 150 and the common source/drain regions 140 have been all formed, in order to activate the implanted ions.

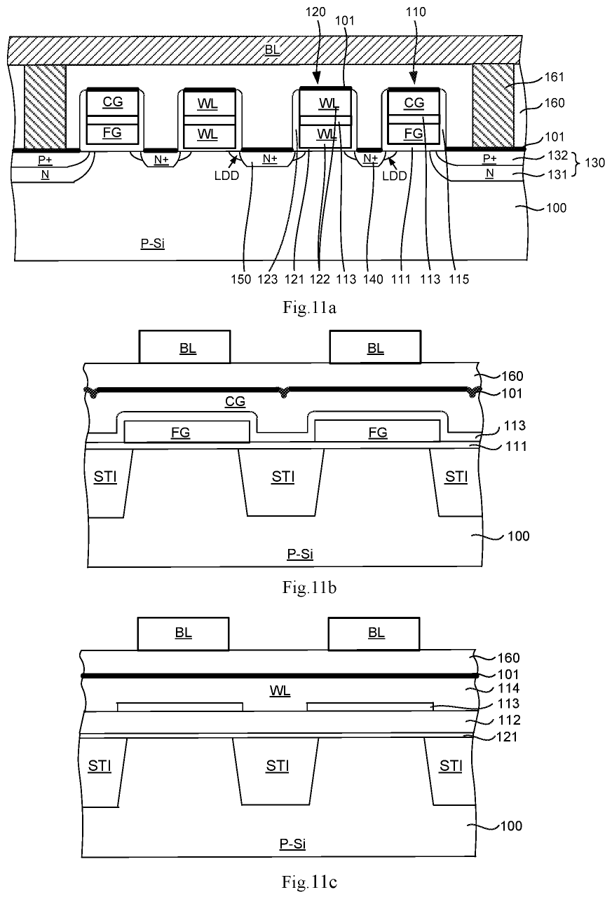

Referring to FIGS. 11a to 11c, the formation of the source regions 150 and the common source/drain regions 140 in the semiconductor substrate 100 may include the process detailed below.

First of all, an N-type LDD implantation process is performed on portions of the active areas between the first stacked gates 110 and the second stacked gates 120 and on portions of the active areas on the side of the second stacked gates 120 away from the first stacked gates 110, thus forming N-type LDD regions in the semiconductor substrate 100. Specifically, the LDD implantation process may be performed on the active area portions where the common source/drain regions 140 and the source regions 150 are to be formed through using a patterned photoresist layer (not shown) as a mask. After the photoresist layer is removed, an annealing process is carried out, thus resulting in the formation of the LDD regions in the semiconductor substrate 100. In this embodiment, the LDD regions are located in the active area portions between the first stacked gates 110 and the second stacked gates 120 and the active area portions on the side of the second stacked gates 120 away from the first stacked gates 110. After that, spacers 115, 123 are formed on sidewalls of the first stacked gates 110 and the second stacked gates 120.

Next, N-type ions are implanted with the use of a mask, followed by the performance of an annealing process, thus forming the common source/drain regions 140 and the source regions 150 in the semiconductor substrate 100. Specifically, another patterned photoresist layer (not shown) is formed over the semiconductor substrate 100, with the regions where the common source/drain regions 140 and the source regions 150 being exposed. After the N-type ions are implanted, the photoresist layer is removed, and an annealing process is then carried out, resulting in the formation of the common source/drain regions 140 and the source regions 150. In this embodiment, the common source/drain regions 140 are situated in the active areas between the first stacked gates 110 and the second stacked gates 120, and the source regions 150 are situated in the active areas on the side of the second stacked gates 120 away from the first stacked gates 110.

From the above steps, a memory cell array composed of at least a 2T memory cell can be obtained. Each 2T memory cell includes an N-channel memory transistor which in turn includes a drain region 130, a first stacked gate 110 and a common source/drain region 140. The 2T memory cell further includes an N-channel select transistor which in turn includes the common source/drain region 140, a second stacked gate 120 and a source region 150.

Referring to FIGS. 11a to 11c, after the source regions 150, the drain regions 130 and the common source/drain regions 140 are formed in the semiconductor substrate 100, according to embodiments of the present invention, the fabrication method may further include the processes below.

A silicide layer 101 is formed over the semiconductor substrate 100. The silicide layer 101 is located on top surfaces of the above-described control gates (CG), select gates 122, source regions 150, drain regions 130 and common source/drain regions 140.

After that, an interlayer dielectric layer 160 and contact plugs 161 each extending through the interlayer dielectric layer 160 are formed over the semiconductor substrate 100. The contact plugs 161 are connected to the drain regions 130 via the silicide layer 101. Afterward, bit lines (BL) connected to the contact plugs 161 are formed on the interlayer dielectric layer 160. The drain regions 130 in the individual 2T memory cells can be electrically connected via the bit lines.

Embodiments of the present invention also relate to a control method for a non-volatile memory. The control method may include a program, erase or read operation performed on a selected 2T memory cell in the non-volatile memory described in connection with the foregoing embodiments. The control method will be described below with reference to FIGS. 1 and 2 in the exemplary context with the 2T memory cell on the left in FIG. 1 being implemented as the selected 2T memory cell and the 2T memory cell on the right as an unselected 2T memory cell. When describing the operation on the selected 2T memory cell in the memory cell array, for the sake of brevity, a word line (WL) connected to the selected 2T memory cell is referred to as a selected word line, each remaining word line as an unselected word lines, a bit line (BL) connected to the selected 2T memory cell as a selected bit line, each remaining bit line as an unselected bit line, a control gate line connected to the selected 2T memory cell as a selected control gate line and each remaining control gate line as an unselected control gate lines.

In one embodiment, during a program operation on the selected 2T memory cell in the memory cell array, the semiconductor substrate 100 is grounded, with the source regions 150 in the individual 2T memory cells being grounded or floating, and the common source/drain regions 140 in the individual 2T memory cells being also grounded or floating. Moreover, a preset negative bias voltage is applied to the drain region 130 in the selected 2T memory cell via the selected bit line (BL), and a preset positive bias voltage is applied to the control gate in the selected 2T memory cell via the selected control gate line (CG).

Table 1 presents bias voltage conditions for the program operation performed on the selected 2T memory cell in the memory cell array of FIG. 2 (e.g., the 2T memory cell indicated by the dashed box in FIG. 2) according to an embodiment of the present invention. Referring to Table 1, during the program operation on the selected 2T memory cell, a bias voltage on the selected word line (WL) ranges from 0 V to Vdd (power supply voltage) or does not need to be taken care of, and the unselected word line is grounded (0 V). Moreover, the bias voltage on the selected control gate line ranges from 8 V to 14 V, and the unselected control gate line is applied with a bias voltage ranging from −3 V to 0 V. In addition, the bias voltage on the selected bit line (BL) ranges from −12 V to −6 V, and the unselected bit line (BL) is applied with a bias voltage of 0 V or floating. Further, the source regions (i.e., source lines (SL)) in the individual 2T memory cells (including the selected 2T memory cell) are grounded or floating, and the semiconductor substrate 100 is grounded (0 V).

TABLE 1
Program Bias Conditions

| Terminal | Bias Voltage |
|---|---|
| selected WL | 0 V to Vdd or don't care |
| unselected WL | 0 V |
| selected CG | 8 V to 14 V |
| unselected CG | −3 V to 0 V |
| source lines | 0 V or floating |
| selected BL | (−6) V to (−12) V |
| unselected BL | 0 V or floating |
| semiconductor substrate | 0 V |

During the above program operation, when the bias voltage on the selected control gate line reaches the preset positive bias voltage (VCG>0, e.g., from 8 V to 14 V), in the selected 2T memory cell, electrons will accumulate in region 131 around a lower surface of the tunneling dielectric layer 111 (“Electron accumulation Region” in FIG. 1), resulting in a lower band-to-band tunneling voltage of the P+/N junction formed by the heavily P-type doped region 132 and the N-type doped region 131 in the drain region 130 and hence a higher probability of tunneling. When the selected bit line applies a preset bias voltage (e.g., from −12 V to −6 V) to the heavily P-type doped region 132 in the drain region 130 via a corresponding contact plug 161, band-to-band tunneling will readily occur in the P+/N junction. As a result, electrons tunnel from the heavily P-type doped region 132 into the N-type doped region 131. Electrons in the N-type doped region 131 are subject to a vertical electric field between the control gate (CG) and the semiconductor substrate 100 and injected into the floating gate (FG), thus accomplishing the program operation. The electrons injected into the floating gate (FG) may be those resulting from the band-to-band tunneling. This reduces the need of electrons from the channel in the selected 2T memory cell for the programming process, thereby allowing a relative low programming current.

Additionally, in the above programming process, the bias voltage on the unselected control gate line is preferably negative or OV (VCG≤0, e.g., higher than −3 V and lower than or equal to 0 V). As a result, in the unselected 2T memory cell, electrons in regions 131 around a lower surface of the tunneling dielectric layer 111 are depleted (“Depletion Region” in FIG. 1), making band-to-band tunneling difficult to occur in the P+/N junction in the drain region 130 of the unselected 2T memory cell and leading to a very low or zero probability of tunneling. Therefore, it is unlikely for electrons in the drain region 130 to be injected into the floating gate (FG) and undesirably interfere with the programming process.

In one embodiment, during an erase operation on the selected 2T memory cell in the non-volatile memory, the semiconductor substrate 100 is grounded, and any one of the source region 150, the drain region 130 and the common source/drain region 140 in the selected 2T memory cell is grounded or floating. Moreover, a preset negative bias voltage is applied to the control gate (CG) in the selected 2T memory cell via the selected control gate line.

Table 2 presents bias voltage conditions for the erase operation performed on the selected 2T memory cell in the memory cell array of FIG. 2 according to an embodiment of the present invention. The bias voltage data in Table 2 can be applied to the semiconductor substrate 100 not provided with the above-described triple-well structures. Referring to Table 2, during the erase operation on the selected 2T memory cell, all the word lines (WL) are applied with a bias voltage which ranges from 0 V to Vdd (power supply voltage) or does not need to be taken care of. The bias voltage on the selected control gate line ranges from −8 V to −16 V, and the unselected control gate line is grounded (0 V). Additionally, the source regions in the individual 2T memory cells (including the selected and unselected 2T memory cells) (i.e., the source lines (SL)) are grounded or floating. Further, all the bit lines (BL) are grounded or floating, and the semiconductor substrate 100 is grounded (0 V).

TABLE 2
Erase Bias Conditions

| Terminal | Bias Voltage |
|---|---|
| all WL | 0 V to Vdd or don't care |
| selected CG | (−8) V to (−16) V |
| unselected CG | 0 V |
| SL | 0 V or floating |
| all BL | 0 V or floating |
| semiconductor substrate | 0 V |

Table 3 presents bias voltage conditions for the erase operation performed on the selected 2T memory cell in the memory cell array of FIG. 2 according to another embodiment of the present invention, which are applicable to the semiconductor substrate 100 provided with the above-described triple-well structures. In this case, the semiconductor substrate 100 is P-type doped and can be separately applied with a voltage. In the semiconductor substrate 100, N-type doped wells are formed, each of which can be applied with a voltage via a corresponding pick-up region on the surface of the semiconductor substrate 100 (i.e., an n-well terminal). In the N-type doped wells, respective P-type doped wells are formed, each of which can be applied with a voltage via a corresponding pick-up region on the surface of the semiconductor substrate 100 (i.e., a p-well terminal). The individual 2T memory cells are arranged in the P-type doped wells. Erase conditions for a 2T memory cell formed on such a triple-well structure may differ from those for a 2T memory cell directly formed on the P-type doped semiconductor substrate 100. Referring to Table 3, during the erase operation performed on the selected 2T memory cell being formed on a triple-well structure, all the word lines are applied with a bias voltage which ranges from 0 V to Vdd (power supply voltage) or does not need to be taken care of. The selected control gate line is applied with a bias voltage ranging from −4 V to −8 V, and the unselected control gate line is grounded (0 V). The source regions in the individual 2T memory cells (i.e., the source lines (SL)) are grounded, and all the bit lines grounded or floating. In the triple-well structure, the semiconductor substrate 100 and the N-type doped well are grounded (0 V), and the P-type doped well is applied with a bias voltage of from 4 V to 8 V.

TABLE 3
Erase Bias Conditions (Triple-Well Structure)

| Terminal | Bias Voltage |
|---|---|
| all WL | 0 V to Vdd or don't care |
| selected CG | (−4) V to (−8) V |
| unselected CG | 0 V |
| SL | 0 V |
| all BL | 0 V or floating |
| P-well | 4 V to 8 V |
| N-well | 0 V |
| semiconductor substrate | 0 V |

This erase operation may be accomplished in a block-wise manner. In this case, a plurality of selected 2T memory cells can be erased at the same time. As each of the control gate lines that they are connected to is applied with a negative bias voltage (e.g., −8 V to −16 V), electrons are expelled from the floating gates (FG). When electrons leave the floating gates, the threshold voltage (Vth) values of the memory transistors become lower.

In the case of the 2T memory cells being formed on the triple-well structures, the ease voltage applied on the selected 2T memory cell has two parts, i.e., the negative bias voltage on the selected control gate line (e.g., in the range of from −4 V to −8 V) and the positive bias voltage applied to the P-type doped well (e.g., from 4 V to 8 V).

In one embodiment, during a read operation on the selected 2T memory cell in the non-volatile memory, the semiconductor substrate 100 is grounded, and the source region 150 and the common source/drain region 140 in the selected 2T memory cell are also grounded. A preset read voltage is applied to the control gate (CG) in the selected 2T memory cell via the selected control gate line. Further, a preset positive bias voltage is applied to the drain region 130 in the selected 2T memory cell via the selected bit line, and the power supply voltage (Vdd) is applied to the select gate 122 in the selected 2T memory cell via the selected word line.

Table 4 presents bias voltage conditions for the read operation performed on the selected 2T memory cell in the memory cell array of FIG. 2 according to an embodiment of the present invention. Referring to Table 4, in order to read a datum stored in the selected 2T memory cell, the power supply voltage (Vdd) is applied as a bias voltage to the selected word line, and all the remaining word lines are grounded (0 V). All the control gate lines or only the selected control gate line are/is applied with a bias voltage ranging from −2 V to 2 V (e.g., 0 V), and the bias voltage on the selected bit line (BL) ranges from 1 V to 3 V, with each remaining bit line being applied with a bias voltage of 0 V or floating. The source regions in the individual 2T memory cells (i.e., the source lines (SL)) are grounded, and the semiconductor substrate 100 is also grounded.

TABLE 4
Read Bias Conditions

| Terminal | Bias Voltage |
|---|---|
| selected WL | Vdd |
| unselected WL | 0 V |
| selected CG | (−2)-(+2) V |
| SL | 0 V |
| selected BL | 1 V to 3 V |
| unselected BL | 0 V or floating |
| semiconductor substrate | 0 V |

Specifically, during the read operation, under the bias voltage conditions shown in the above table, if the floating gate (FG) in the selected 2T memory cell has a low Vth value, the applied CG bias can turn on the memory transistor, and there will be a cell current flowing from the selected bit line (BL) through the 132/131 P+/N junction and the channels of the N-channel memory and select transistors to the source 150. Upon detecting this, it can be determined that the selected 2T memory cell is in an ON state. If the floating gate (FG) in the selected 2T memory cell is negative charged, no such cell current will be detected, and it can be determined that the selected 2T memory cell is in an OFF state. In this embodiment, the N-channel select transistors are so configured that, during the read operation on the selected 2T memory cell, the word lines that the remaining 2T memory cells are connected to, i.e., the unselected word lines, are all applied with a voltage of 0 V. As a result, the N-channel select transistors in all the remaining 2T memory cells are OFF. Thus, even when the N-channel memory transistor in any one of the remaining 2T memory cells is over erased and turned on, there will be no current path being established, avoiding erroneous data determination.

In the non-volatile memory described above in connection with the foregoing embodiments, during an erase operation on a 2T memory cell, even when the channel under the floating gate (FG) tends to be turned on before the control gate voltage reaches the operating voltage due to over erase, the N-channel select transistor can cause the channel between the common source/drain region 140 and the source region 150 to remain OFF to prevent the channel of the 2T memory cell from being turned on. This can avoid erroneous data determination caused by over erase. Moreover, since each 2T memory cell is made up of an N-channel memory transistor and a N-channel select transistor, and as the mobility of electrons is higher than that of holes, a relative high reading current is allowed in a read operation. Further, during a program operation, electrons accumulate in the N-type doped region 131 in the drain region 130, resulting in a lower band-to-band tunneling voltage of the P+/N junction formed by the heavily P-type doped region 132 and the N-type doped region 131 in the drain region 130 and a high probability of tunneling. Under the action of an appropriate control gate voltage and drain voltage (i.e., bit line voltage), electrons that have tunneled can be injected into the floating gate, reducing the need for electrons in the channel and allowing the use of a lower programming current.

The foregoing description is merely that of several preferred embodiments of the present invention and is not intended to limit the scope of the claims of the invention in any way. Any person of skill in the art may make various possible variations and changes to the disclosed embodiments in light of the methodologies and teachings disclosed hereinabove, without departing from the spirit and scope of the invention. Accordingly, any and all such simple variations, equivalent alternatives and modifications made to the foregoing embodiments based on the essence of the present invention without departing from the scope of the embodiments are intended to fall within the scope of protection of the invention.

What is claimed is:

1. A non-volatile memory comprising at least one two-transistor (2T) memory cell, wherein each 2T memory cell comprises:
a semiconductor substrate;
a first stacked gate formed on the semiconductor substrate, wherein the first stacked gate comprises a tunneling dielectric layer, a floating gate, an inter-gate dielectric layer and a control gate;
a second stacked gate formed on the semiconductor substrate, wherein the second stacked gate comprises a select gate dielectric layer and a select gate;
a drain region formed in the semiconductor substrate and situated on a side of the first stacked gate away from the second stacked gate;
a common source/drain region formed in the semiconductor substrate and situated between the first stacked gate and the second stacked gate; and
a source region formed in the semiconductor substrate and situated on a side of the second stacked gate away from the first stacked gate.

2. The non-volatile memory of claim 1, wherein: the source region and the common source/drain region are N-type doped regions; and the N-type doped region comprises a heavily N-type doped region and an N-type LDD region, and
wherein: the drain region comprises an N-type doped region and a heavily P-type doped region formed in the N-type doped region; and the N-type doped region in the drain region extends laterally to a position below a portion of the first stacked gate.

3. The non-volatile memory of claim 1, further comprises a mirrored 2T memory cell which shares the source region with the 2T memory cell, and wherein a plurality of 2T memory cells and a plurality of mirrored 2T memory cells form a memory cell array.

4. The non-volatile memory of claim 3, wherein the control gates in the 2T memory cells and in the mirrored 2T memory cells are respectively connected to form control gate lines, wherein the select gates in the 2T memory cells and in the mirrored 2T memory cells are respectively connected to form word lines, and wherein the source regions are connected to form source lines.

5. The non-volatile memory of claim 4, wherein the control gate in each 2T memory cell is adjacent and parallel to the control gate in a corresponding mirrored 2T memory cell.

6. The non-volatile memory of claim 3, further comprising:
an interlayer dielectric layer covering the 2T memory cells and the mirrored 2T memory cells;
a plurality of contact plugs extending through the interlayer dielectric layer, wherein each of the plurality of contact plugs is connected to a corresponding drain region; and
a plurality of bit lines, respectively connected to the drain regions in the 2T memory cells and to the drain regions in the mirrored 2T memory cells via the corresponding contact plugs.

7. The non-volatile memory of claim 1, wherein the semiconductor substrate is a P-type doped substrate, and wherein the source region, the common source/drain region and the drain region in each 2T memory cell are formed in a top portion of the P-type doped substrate.

8. The non-volatile memory of claim 1, wherein the semiconductor substrate contains a triple-well structure comprising an N-type doped well in a P-type doped substrate and a P-type doped well in the N-type doped well, and wherein the source region, the common source/drain region and the drain region in each 2T memory cell are formed in a top portion of the P-type doped well.

9. A method for fabricating a non-volatile memory, comprising:
providing a semiconductor substrate;
forming a plurality of isolation regions in the semiconductor substrate, adjacent isolation regions defining an active area therebetween;
forming a first stacked gate and a second stacked gate on the active area, wherein the first stacked gate comprises a tunneling dielectric layer, a floating gate, an inter-gate dielectric layer and a control gate; and the second stacked gate comprises a select gate dielectric layer and a select gate;
forming a drain region, wherein the drain region is situated on a side of the first stacked gate away from the second stacked gate, and wherein the drain region comprises an N-type doped region and a heavily P-type doped region formed in the N-type doped region; and
forming a source region and a common source/drain region, wherein the source region is situated on a side of the second stacked gate away from the first stacked gate, wherein the common source/drain region is situated between the first stacked gate and the second stacked gate, and wherein each of the source region and the common source/drain region is N-type doped.

10. The method of claim 9, wherein the formation of the drain region comprises:
successively implanting N-type ions and P-type ions into a portion of the active area on the side of the first stacked gate away from the second stacked gate to form the N-type doped region and the heavily P-type doped region.

11. The method of claim 10, wherein the N-type ions are implanted at an energy of from 80 KeV to 150 KeV and a dose of from 8E12 cm⁻² to 8E14 cm⁻².

12. The method of claim 10, wherein the P-type ions are implanted at an energy of from 5 KeV to 25 KeV and a dose of from 1E15 cm⁻² to 1E16 cm⁻².

13. The fabrication of claim 9, wherein the formation of the source region and the common source/drain region comprises:
performing an N-type lightly doped drain (LDD) implantation process between the first stacked gate and the second stacked gate and on the side of the second stacked gate away from the first stacked gate;
forming spacers on sidewalls of the first stacked gate and the second stacked gate respectively; and
implanting N-type ions into the portion of the active area between the first stacked gate and the second stacked gate, and on the side of the second stacked gate away from the first stacked gate, to form the common source/drain region and the source region.

14. The method of claim 9, wherein the formation of the first stacked gate and the second stacked gate comprises:
forming a tunneling dielectric layer and a select gate dielectric layer over the semiconductor substrate;
forming a first conductive material layer over the tunneling dielectric and the select gate dielectric layers and forming first openings in the first conductive material layer, wherein the first openings are located in positional correspondence with the isolation regions, and wherein the tunneling dielectric layer is exposed in the first openings;
forming an inter-gate dielectric layer on the first conductive material layer and forming second openings in the inter-gate dielectric layer, wherein the second openings are located on the select gate dielectric layer and in positional correspondence with the isolation regions, and wherein the first conductive material layer is exposed in the second openings; and
forming a second conductive material layer on the inter-gate dielectric layer and performing photolithography and etching processes on the second conductive material layer, the inter-gate dielectric layer and the first conductive material layer to form at least one gate, wherein the gate on the select gate dielectric layer is select gate.

15. The method of claim 14, wherein the first conductive material layer and the second conductive material layer are directly connected at locations corresponding to the isolation regions.

16. The method of claim 9, further comprising, subsequent to the formation of the source region, the drain region and the common source/drain region:
forming a silicide layer on a top surface of each of the control gate, the select gate, the source region, the drain region and the common source/drain region;
depositing an interlayer dielectric layer and forming contact plugs extending through the interlayer dielectric layer and connected to the respective drain regions; and
forming, on the interlayer dielectric layer, bit lines connected to the respective contact plugs.

17. The method of claim 9, wherein the N-type doped region in the drain region laterally extends to a position below a portion of the floating gate.

18. A method for controlling a non-volatile memory, comprising a program operation performed on a selected 2T memory cell in the non-volatile memory as defined in claim 1, wherein the program operation comprises:
grounding the semiconductor substrate; grounding or floating either of the source region and the common source/drain region in the selected 2T memory cell; applying a preset negative bias voltage to the drain region in the selected 2T memory cell; and applying a preset positive bias voltage to the control gate in the selected 2T memory cell.

19. The method of claim 18, further comprising an erase operation comprising:
grounding the semiconductor substrate; grounding or floating any one of the source region, the drain region and the common source/drain region in the selected 2T memory cell; and applying a preset negative bias voltage to the control gate in the selected 2T memory cell.

20. The method of claim 18, further comprising a read operation comprising:
grounding the semiconductor substrate, the source region and the common source/drain region in the selected 2T memory cell; applying a preset read voltage to the control gate in the selected 2T memory cell; applying a preset positive bias voltage to the drain region in the selected 2T memory cell; and applying a power supply voltage to the select gate in the selected 2T memory cell.
